(19) United States
(12) Patent Application Publication
(10) Pub. No.: US 2026/0282439 A1
(43) Pub. Date: Sep. 17, 2026

(54) TRENCH GATE MOSFET AND A METHOD FOR FABRICATING THE SAME

(71) Applicant: Silicon-Magic Semiconductor Technology (Hangzhou) Co., Ltd., Hangzhou (CN)

(72) Inventors: Jinyong CAI, Hangzhou (CN); Xueqin LI, Hangzhou (CN); Wei HUANG, Hangzhou (CN); Jiakun WANG, Hangzhou (CN)

(73) Assignee: Silicon-Magic Semiconductor Technology (Hangzhou) Co., Ltd., Hangzhou (CN)

(21) Appl. No.: 19/565,586

(22) Filed: Mar. 13, 2026

(30) Foreign Application Priority Data
Mar. 14, 2025 (CN) 2025103122259

(51) Int. Cl. H10D 30/66; H10D 30/01; H10D 30/60; H10D 62/10

(52) U.S. Cl. CPC H10D 30/668; H10D 30/023; H10D 30/0295; H10D 30/0297; H10D 30/611; H10D 62/102; H10D 62/124

(57) ABSTRACT

A method for fabricating a trench gate MOSFET, including: providing a semiconductor substrate; forming an epitaxial layer overlying the semiconductor substrate; forming a plurality of trenches in the epitaxial layer; forming a first dielectric layer to cover an inner surface of each trench; forming a second dielectric layer to cover the first dielectric layer; forming a first shield gate in a lower portion of each trench; removing an upper portion of the second dielectric layer to expose an upper portion of the first dielectric layer; forming a second shield gate on the first shield gate to form a shieled gate; forming an intermediate insulating layer to cover the shield gate in each trench; removing the upper portion of the first dielectric layer above the intermediate insulating layer to expose an upper portion of each trench; and forming a control gate on the intermediate insulating layer in each trench.

### CROSS-REFERENCE TO RELATED APPLICATION

This application claims the benefit of Chinese patent application No. 202510312225.9, filed on Mar. 14th, 2025, which is incorporated herein by reference in its entirety.

### TECHNICAL FIELD

The present disclosure belongs to the technical field of semiconductors, and in particular to a trench gate MOSFET (Metal Oxide Semiconductor Field Effect Transistor) and a method for fabricating the same.

### BACKGROUND

The Metal-Oxide-Semiconductor Field-Effect Transistor (MOSFET) is a widely used power semiconductor device, commonly employed as a switch in power converters. The MOSFET may have a planar structure or a vertical structure.

Based on the vertical structure MOSFET, the trench gate MOSFET has been developed. The structure of the trench gate MOSFET is as shown in FIG. 1, which includes a semiconductor substrate, an epitaxial layer formed on the semiconductor substrate, trenches formed in the epitaxial layer, and a gate structure formed in a corresponding trench. The gate structure includes a gate conductor and a gate dielectric insulating the gate conductor from the trench. The trench gate structure of the MOSFET provides a short source-drain current path, thereby reducing the on-resistance and thus significantly reducing the power loss. However, the breakdown voltage performance of the prior art trench gate MOSFET is poor. In conventional technologies, to increase the breakdown voltage, a field plate structure including a field conductor and a dielectric layer is formed at the lower portion of the trench to modulate the electric field in the drift region. However, as indicated by the electric field lines on the right side of FIG. 1, the electric field in the central portion of the drift region remains weak, limiting the device’s breakdown voltage. Particularly on the device’s blocking state, the non-uniform distribution of the electric field in the drift region prevents further increase of the device’s breakdown voltage.

Therefore, it is necessary to propose a new trench gate MOSFET and a manufacturing method thereof to solve the above problems.

### SUMMARY

An objective of the present invention is to provide a trench gate MOSFET with high breakdown voltage.

An example of the present disclosure relates to a method for fabricating a trench gate MOSFET. The method includes: providing a semiconductor substrate; forming an epitaxial layer overlying the semiconductor substrate, wherein the epitaxial layer has a first surface and a second surface adjoining the semiconductor substrate; forming a plurality of trenches in the epitaxial layer, wherein each one of the plurality of trenches is extended from the first surface to an interior of the epitaxial layer; forming a first dielectric layer to cover an inner surface of each one of the plurality of trenches and the first surface of the epitaxial layer; forming a second dielectric layer to cover the first dielectric layer in each one of the plurality of trenches; forming a first shield gate in a lower portion of each one of the plurality of trenches; removing an upper portion of the second dielectric layer to expose an upper portion of the first dielectric layer in each one of the plurality of trenches; forming a second shield gate on the first shield gate in each one of the plurality of trenches, wherein the second shield gate adjoins part of the exposed upper portion of the first dielectric layer, and wherein the first shield gate and the second shield gate form a shieled gate; forming an intermediate insulating layer to cover the shield gate in each one of the plurality of trenches; removing the upper portion of the first dielectric layer above the intermediate insulating layer to expose an upper portion of each one of the plurality of trenches, and removing the first dielectric layer on the first surface of the epitaxial layer; and forming a control gate on the intermediate insulating layer in each one of the plurality of trenches.

Another example of the present disclosure relates to a trench gate MOSFET. The trench gate MOSFET includes: a semiconductor substrate; an epitaxial layer overlying the semiconductor substrate, wherein the epitaxial layer has a first surface and a second surface adjoining the semiconductor substrate; a plurality of trenches extending from the first surface of the epitaxial layer to an interior of the epitaxial layer; a shield gate formed in a lower portion of each one of the plurality of trenches, wherein the shield gate comprises a first shield gate and a second shield gate which is wider than the first shield gate in a lateral direction; a first dielectric layer insulating the second shield gate from the trench in each one of the plurality of trenches; a second dielectric layer, together with the first dielectric layer, insulating the first shield gate from the trench in each one of the plurality of trenches; a control gate formed in an upper portion of the trench in each one of the plurality of trenches, wherein the control gate is insulated from the shield gate by an intermediate insulating layer; and a gate dielectric layer insulating the control gate from the trench and covering the control gate in each one of the plurality of trenches.

Those skilled in the art will recognize additional features and advantages upon reading the following detailed description, and upon viewing the accompanying drawings.

### BRIEF DESCRIPTION OF THE DRAWINGS

FIG. 1 schematically shows a prior art trench gate MOSFET;

FIGS. 2a - 2j schematically illustrate cross-sectional views at various stages of a fabrication process for a trench gate MOSFET in accordance with an embodiment of the present disclosure.

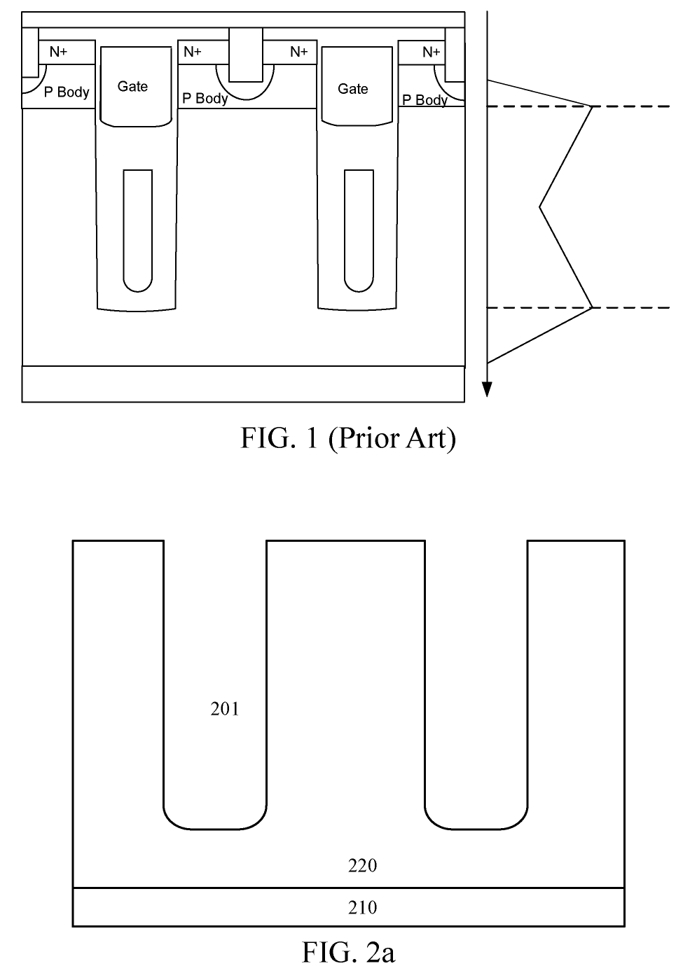

### DETAILED DESCRIPTION

The embodiments of the present disclosure will be specifically described below through specific examples. Those skilled in the art can easily understand the other advantages and effects of the present disclosure from the content disclosed in this description. The present disclosure may also be implemented or applied through other different specific implementations, and the details in this description may be modified or changed based on different perspectives and applications without deviating from the spirit of the present disclosure.

It should be emphasized that the term "including/comprising" when used herein refers to the presence of a feature, integral part, step, or component, but does not exclude the presence or addition of one or more other features, integral parts, steps, or components.

The features described and/or indicated for one implementation may be used in the same or similar manner in one or more other implementations, combined with features in other implementations, or substituted for features in other implementations.

When describing the embodiments of the present disclosure in detail, for ease of description, a schematic diagram representing an apparatus structure will be enlarged out of a general scale, and the schematic diagram is only an example, which should not limit the scope of protection of the present disclosure. In addition, in actual fabrication, the three-dimensional spatial dimensions of length, width, and depth should be included.

For the convenience of description, spatial relationship words such as "under", "below", "lower than", "underneath", "above" and "over" may be used here to describe the relationship between one element or feature and other elements or features shown in the figure. It is to be understood that these spatial relationship words are intended to include directions for devices in use or operation in addition those depicted in the figures. In addition, when a layer is referred to as "between" two layers, it may be the only layer between the two layers, or there may be one or more layers therebetween.

In the context of this application, a structure described where a first feature is "above" a second feature may include embodiments where the first feature and second feature form direct contact, or embodiments where additional features are formed between the first structure and second feature, such that the first feature and second feature may not be in direct contact.

It should be noted that the drawings provided in the embodiments are only intended to schematically describe the basic concept of the present disclosure. Therefore, the drawings only display the components related to the present disclosure, and are not drawn according to the number, shape, and size of the components during actual implementation. The type, number, and scale of each component during actual implementation may be freely changed, and the layout pattern of the component may also be more complex.

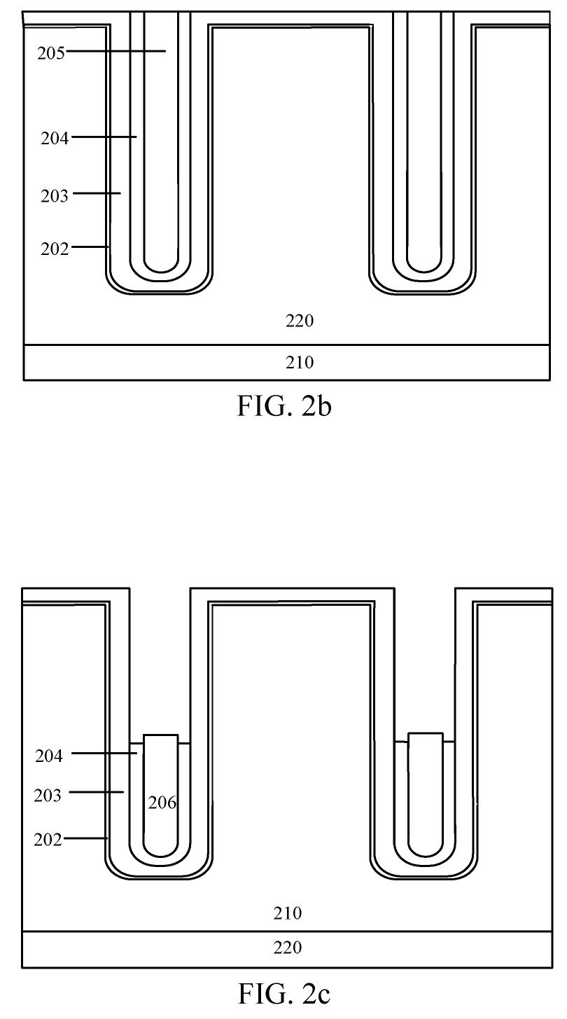

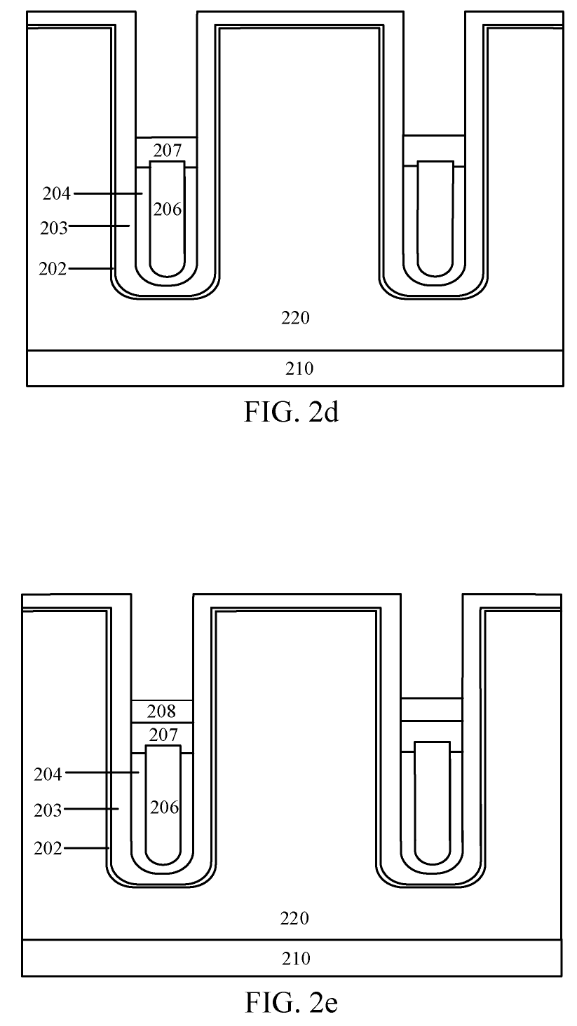

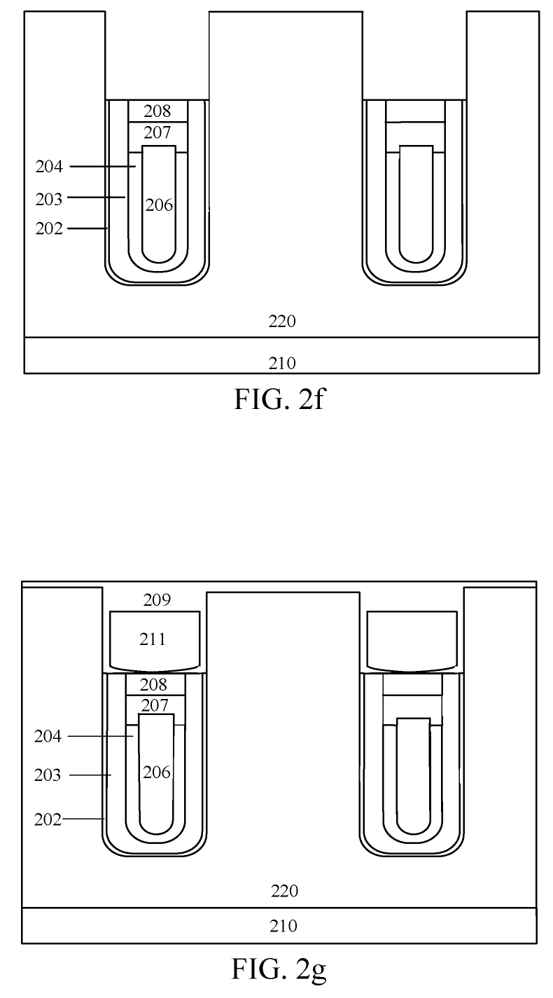

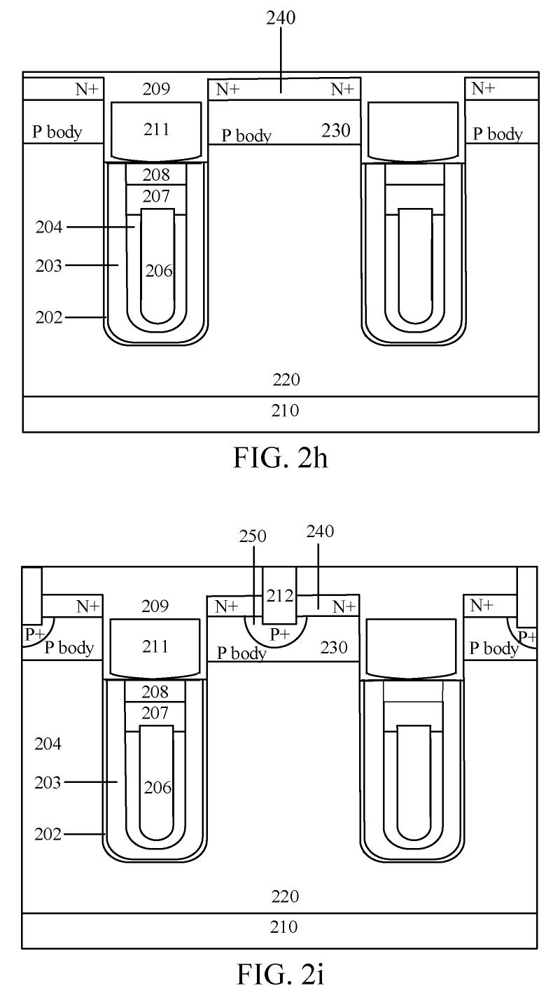

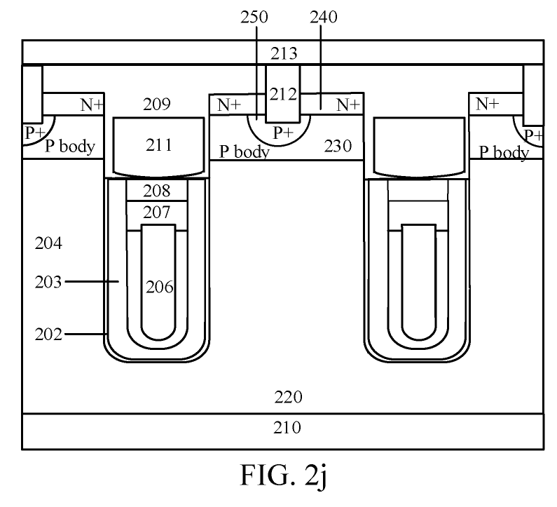

FIGS. 2a to 2j illustrate cross-sectional views at various stages of a method for manufacturing a trench gate MOSFET in accordance with an embodiment of the present disclosure. The method includes steps S01 through S13.

In step S01, an epitaxial layer 220 of a first conductivity type is formed on a semiconductor substrate 210 of the first conductivity type.

Known deposition processes may be employed to form the epitaxial layer 220, such as electron beam evaporation (EBM), chemical vapor deposition (CVD), atomic layer deposition (ALD), sputtering, or the like. The semiconductor substrate 210 is, for example, a monocrystalline silicon substrate, and the epitaxial layer 220 is, for example, a monocrystalline silicon epitaxial layer. In one embodiment, the semiconductor substrate 210 is heavily doped, and the epitaxial layer 220, from top to bottom (i.e., from the region distal to the semiconductor substrate 210 to the region proximal to the semiconductor substrate 210), sequentially includes a lightly doped layer, a moderately doped layer, and a heavily doped layer. When the first conductivity type is N type doping, the semiconductor substrate is N+ doped, and the epitaxial layer 220, from top to bottom, sequentially includes an N- doped layer, an N doped layer, and an N+ doped layer.

In step S02, a sacrificial oxide layer (not shown) is formed, for example, on the surface of the epitaxial layer 220. Subsequently, a photoresist layer is formed on the sacrificial oxide layer, followed by an etching process. The etching process may be a dry etching process, such as ion milling etching, plasma etching, reactive ion etching, laser ablation, or a selective wet etching using an etchant solution. Etching proceeds downward from openings in the photoresist mask to the sacrificial oxide layer to form openings in the sacrificial oxide layer, thereby patterning the sacrificial oxide layer into a hard mask. Due to the selectivity of the etching, the etching may stop at the surface of the epitaxial layer 220. After forming the hard mask, the photoresist layer is removed by dissolving in a solvent or ashing.

Subsequently, using the hard mask, the epitaxial layer 220 is further etched via the aforementioned known etching processes to form trenches 201 within the epitaxial layer 220. The trenches 201 extend from the first surface (top surface) of the epitaxial layer 220 into the epitaxial layer 220. The depth of the trenches 201 may be controlled by controlling the etching time. The trenches 201 terminate within the N doped layer of the epitaxial layer 220. After forming the trenches 201, the hard mask could be removed by a selective etchant. After steps S01 and S02, a structure as shown in FIG. 2a is obtained.

In step S03, a first dielectric layer is formed on the inner surface of the trenches 201 and the first surface of the epitaxial layer 220.

The first dielectric layer is formed via the aforementioned known deposition processes. The first dielectric layer includes a first insulating layer 202 and a second insulating layer 203 conformal with the first insulating layer 202 sequentially formed on the inner surface of the trenches 201 and the first surface of the epitaxial layer 220. The first insulating layer 202 adjoints the inner surface of the trenches 201 and the first surface of the epitaxial layer 220. In one embodiment, the first insulating layer 202 is an oxide layer (e.g., a silicon oxide layer), and the second insulating layer 203 is a nitride layer (e.g., a silicon nitride layer). The thickness of the first insulating layer 202 ranges from 0.1 µm to 0.3 µm, and the thickness of the second insulating layer 203 ranges from 0.2 µm to 0.4 µm.

In step S04, a second dielectric layer 204 is formed on the first dielectric layer inside the trenches 201.

The second dielectric layer 204 may have a top surface flushing with a top surface of the second insulating layer 203 formed on the epitaxial layer 220. In one embodiment, the second dielectric layer 204 is an oxide layer (e.g., a silicon oxide layer). The thickness of the second dielectric layer 204 ranges from 0.1 µm to 2 µm.

It should be noted that the specific compositions of the first dielectric layer and second dielectric layer 204 are provided as examples. In actual applications, the second dielectric layer 204 is designed with a higher etch selectivity relative to the second insulating layer 203, enabling its selective removal while the second insulating layer 203 is preserved.

In step S05, a first shield gate 206 is formed in a lower portion of each trench 201.

A first conductor 205 (e.g., doped polysilicon) is formed in the trench 201 via the aforementioned known deposition processes. The first conductor 205 fills the cavities defined by the second dielectric layer 204. Further, mechanical planarization (e.g., chemical mechanical polishing) is performed to remove the first conductor layer 205 deposited above the second insulating layer 203, thereby obtaining a structure as shown in FIG. 2b.

Subsequently, the first conductor 205 is etched. During etching, the second dielectric layer 204 is preserved while the first conductor 205 is etched dure to different etching rates. The portion of the first conductor 205 remaining in the trench 201 constitutes the first shield gate 206. In one example, a top surface of the first shield gate 206 lies within the vertical extent of the N doped layer of the epitaxial layer 220.

In step S06, the second dielectric layer 204 is etched to expose upper portion of the first dielectric layer in each trench 201.

An etchant selective for removing the second dielectric layer 204 is employed. This etching causes the top surface of the second dielectric layer 204 to be slightly lower than the top surface of the first shield gate 206 as shown in FIG. 2c. The top surface of the second dielectric layer 204 could be flush with the top surface of the first shield gate 206 in other embodiments, After removing the upper portion of the second dielectric layer 204, the upper portion of the first dielectric layer in the trench 201 is exposed. In one embodiment, after etching, the top surface of the second dielectric layer 204 lies within the vertical extent of the N doped layer of the epitaxial layer 220.

In step S07, a second shield gate 207 is formed on the first shield gate 206 and the top surface of the second dielectric layer 204. The first shield gate 206 and the second shield gate 207 together constitute a shield gate.

The second shield gate 207 is formed within the trench 201 via the aforementioned known deposition and etching processes. The second shield gate 207 covers the exposed surface of the first shield gate 206 and the exposed surface of the etched second dielectric layer 204, thereby obtaining a structure as shown in FIG. 2d. The second shield gate 207 and the first shield gate 206 together constitute the shield gate, which is electrically connected to a source terminal. In one embodiment, a top surface of the shield gate is flush with the top surface of the N doped layer of the epitaxial layer 220. As shown in FIG. 2d, the shield gate has a T-shaped structure.

In step S08, an intermediate insulating layer 208 is formed on the exposed surface of the shield gate.

The intermediate insulating layer 208 is formed on the exposed surface of the shield gate via thermal oxidation or chemical vapor deposition. As illustrated in FIG. 2e, the intermediate insulating layer 208 is formed within the trench 201, leaving an upper portion of the trench unfilled. In one embodiment, the intermediate insulating layer 208 is an oxide layer (e.g., a silicon oxide layer).

In step S09, the first dielectric layer is etched to expose the portion of the sidewall of each trench 201 and the first surface of the epitaxial layer 220.

The first dielectric layer and the second dielectric layer 204 form the stepped dielectric layers after etching. Specifically, an etchant is employed to etch the portion of the second insulating layer 203 above the intermediate insulating layer 208, thereby removing the targeted portions of the second insulating layer 203, including exposed portions on the first surface of the epitaxial layer 220 and exposed portions on the sidewall above the intermediate insulating layer 208 in each trench 201. Then, another etchant is employed to etch the exposed portions of the first insulating layer 202, including exposed portions on the first surface of the epitaxial layer 220 and exposed portions on the sidewall above the intermediate insulating layer 208 in each trench 201. Consequently, the upper portion of the sidewall of each trench 201 and the first surface of the epitaxial layer 220 are exposed as shown in FIG. 2f.

In step S10, a control gate 211 is formed in the upper portion of each trench 201.

Specifically, a first layer of a gate dielectric layer 209 is formed to conformally cover the upper portion of the trench 201 and the first surface of the epitaxial layer 220 via the aforementioned known deposition processes firstly. Secondly, a second conductor (e.g., doped polysilicon) is formed to fill the trench 201 via the aforementioned known deposition processes. Further, mechanical planarization (e.g., chemical mechanical polishing) may be performed to remove portions of the second conductor above the epitaxial layer 220, followed by recess etching of the second conductor. After etching, the second conductor constitutes the control gate 211. Subsequently, a second layer of the gate dielectric layer 209 is formed to cover the exposed surface of the control gate 211, via the aforementioned known deposition processes. The first and second layers of the gate dielectric layer 209 merge to wrap the control gate 211 as shown in FIG. 2g. In other embodiments, the first and second layers of the gate dielectric layer 209 may also be formed simultaneously.

In step S11, body regions 230 of a second conductivity type and source regions 240 of the first conductivity type are formed between the trenches 201 within the epitaxial layer 220.

In step S11, conventional body implantation and drive-in techniques are adopted to perform a first ion implantation, forming the body regions 230 of the second conductivity type within the epitaxial layer 220. In one example, the body region 230 is P-type doped. Further, conventional source implantation is employed to perform a second ion implantation, forming the source regions 240 of the first conductivity type in the body regions 230. The source region 240 contacts the gate dielectric layer 209 on the first surface of the epitaxial layer 220. In one embodiment, the source region 240 is N-type doped with a high concentration. The body region 230 and the source region 240 are respectively adjacent to the trench 201, i.e., each trench 201 is laterally flanked by the body regions and the source regions, resulting in a structure as shown in FIG. 2h.

In step S12, contact regions 250 of the second conductivity type are formed within the body regions 230 respectively.

Conventional body implantation is adopted to perform a third ion implantation, forming a contact region 250 of the second conductivity type within a corresponding body region 230. In one example, the contact region 250 is P-type doped with a high concentration.

In step S13, contact structures 212 reaching to the contact region 250 are formed, and a metal layer 213 is then formed on the surface of the gate dielectric layer 209 to contact the contact structures 212.

Specifically, in step S13, photolithograph and etching processes may be employed to pattern the gate dielectric layer 209 on the first surface of the epitaxial layer 220 and the source region 240 to form openings reaching the contact region 250. Further, a third conductor layer is formed in each opening via the aforementioned known deposition processes. The third conductor layer fills the openings. Then, taking the gate dielectric layer 209 on the first surface of the epitaxial layer 220 as a stop layer, mechanical planarization (e.g., chemical mechanical polishing) is performed to remove portions of the third conductor layer disposed outside the openings, forming the contact structures 212 contacting the contact region 250, thereby obtaining a structure as shown in FIG. 2i.

Subsequently, the metal layer 213 is formed on the surface of the gate dielectric layer 209 to contact the contact structures 212, via the aforementioned known deposition processes, thereby obtaining a structure as shown in FIG. 2j. The metal layer 213 serves as a source contact.

The oxide layers mentioned in this disclosure may be of the same type or different types of oxides, which is not specifically limited in this disclosure.

It can be understood that based on the above-described method for manufacturing the trench gate MOSFET, the present disclosure also provides the trench gate MOSFET manufactured by the method, a cross-sectional view of which is shown in FIG. 2j.

Referring to FIG. 2j, the trench gate MOSFET provided by the embodiments of the present disclosure includes the semiconductor substrate 210, the epitaxial layer 220, the trenches 201, the shield gate, the first dielectric layer, the control gate 211, the second dielectric layer 204 and the gate dielectric layer 209. The epitaxial layer 220 is formed on the semiconductor substrate 210. The trenches 201 extend from the first surface of the epitaxial layer 220 into its interior. The shield gate includes the first shield gate 206 and the second shield gate 207 on the first shield gate 206. The second shield gate 207 is laterally wider than the first shield gate 206, forming a T-shaped structure. The first dielectric layer separates the second shield gate 207 from the sidewall of the trench 201. The second dielectric layer 204, together with the first dielectric layer, separates the first shield gate 206 from the sidewall of the trenches 201. The control gate 211 is formed above the shield gate and is separated therefrom by an intermediate insulating layer 208. The gate dielectric layer 209 separates the control gate 211 from the sidewall of the trench 201 and covers an upper surface of the control gate 211 and the first surface of the epitaxial layer 220. The trench gate MOSFET further includes source regions 240, the body regions 230, the contact regions 250 and the metal layer 213. The body region 230 is formed in the epitaxial layer 220 and is between the neighboring trenches 201. The body region 230 is adjacent to the sidewalls of the trenches 201. The source region 240 is formed within the body region 230 and is adjacent to the sidewalls of the trenches 201. The contact region 250 is disposed within the body region 230 and is connected to the metal layer 213 by the contact structure 212 through the source region 240 and the gate dielectric layer 209.

The first dielectric layer includes the first insulating layer 202 and the second insulating layer 203 conformal with the first insulating layer 202. The first insulating layer 202 adjoints the sidewalls of the trenches 201. The second dielectric layer 204 adjoints the first shield gate 206. The second insulating layer 203 is located between the first insulating layer 202 and the second dielectric layer 204. In one embodiment, the first insulating layer 202 is an oxide layer, the second insulating layer 203 is a nitride layer, and the second dielectric layer 204 is an oxide layer. In one embodiment, the epitaxial layer 220, from bottom to top, has a vertically graded doping file, sequentially including a heavily doped layer, a moderately doped layer, and a lightly doped layer. In one embodiment, the source regions and the body regions are positioned in the lightly doped layer of the epitaxial layer.

The above embodiments are only intended to exemplarily describe the principle and effect of the present disclosure, rather than to limit the present disclosure. Any person skilled in the art may modify or change the embodiments without departing from the spirit and scope of the present disclosure. Therefore, all equivalent modifications or changes completed by those with ordinary knowledge in the technical field without departing from the spirit and technical concept disclosed in the present disclosure should still be covered by the claims of the present disclosure.

What is claimed is:

1. A method for fabricating a trench gate MOSFET, comprising:
providing a semiconductor substrate;
forming an epitaxial layer overlying the semiconductor substrate, wherein the epitaxial layer has a first surface and a second surface adjoining the semiconductor substrate;
forming a plurality of trenches in the epitaxial layer, wherein each one of the plurality of trenches is extended from the first surface to an interior of the epitaxial layer;
forming a first dielectric layer to cover an inner surface of each one of the plurality of trenches and the first surface of the epitaxial layer;
forming a second dielectric layer to cover the first dielectric layer in each one of the plurality of trenches;
forming a first shield gate in a lower portion of each one of the plurality of trenches;
removing an upper portion of the second dielectric layer to expose an upper portion of the first dielectric layer in each one of the plurality of trenches;
forming a second shield gate on the first shield gate in each one of the plurality of trenches, wherein the second shield gate adjoins part of the exposed upper portion of the first dielectric layer, and wherein the first shield gate and the second shield gate form a shieled gate;
forming an intermediate insulating layer to cover the shield gate in each one of the plurality of trenches;
removing the upper portion of the first dielectric layer above the intermediate insulating layer to expose an upper portion of each one of the plurality of trenches, and removing the first dielectric layer on the first surface of the epitaxial layer; and
forming a control gate on the intermediate insulating layer in each one of the plurality of trenches.

2. The method for fabricating a trench gate MOSFET of claim 1, wherein forming a control gate comprises:
forming a first gate dielectric layer to cover the first surface of the epitaxial layer and the inner surface of each one of the plurality of trenches after the upper portion of the first dielectric layer above the intermediate insulating layer is removed;
forming the control gate in each one of the plurality of trenches after the first gate dielectric layer is formed; and
forming a second gate dielectric layer to cover the control gate and the first gate dielectric layer, wherein the first gate dielectric layer and the second gate dielectric layer are merged as a gate dielectric layer.

3. The method for fabricating a trench gate MOSFET of claim 2, further comprising:
forming body regions in the epitaxial layer, wherein each one of the plurality of trenches is laterally flanked by two of the body regions;
forming source regions in the body regions respectively;
forming contact regions in the body regions, wherein the contact region is under the respective source region; and
forming contact structures penetrating through the gate dielectric layer and the source regions to reach the contact regions.

4. The method for fabricating a trench gate MOSFET of claim 1, wherein the first dielectric layer comprises a first insulating layer and a second insulating layer, and wherein the first insulating layer adjoins the inner surface of the trench, and the second insulating layer adjoins the second dielectric layer.

5. The method for fabricating a trench gate MOSFET of claim 4, wherein the first insulating layer comprises an oxide layer, and the second insulating layer comprises a nitride layer.

6. The method for fabricating a trench gate MOSFET of claim 4, wherein the first insulating layer has a thickness ranging from 0.1 µm to 0.3 µm, and the second insulating layer has a thickness ranging from 0.2 µm to 0.4 µm.

7. The method for fabricating a trench gate MOSFET of claim 1, wherein, in a direction vertical to the first surface of the epitaxial layer, the epitaxial layer sequentially comprises a lightly doped layer, a moderately doped layer, and a heavily doped layer, with the heavily doped layer being closest to the semiconductor substrate.

8. A trench gate MOSFET, comprising:
a semiconductor substrate;
an epitaxial layer overlying the semiconductor substrate, wherein the epitaxial layer has a first surface and a second surface adjoining the semiconductor substrate;
a plurality of trenches extending from the first surface of the epitaxial layer to an interior of the epitaxial layer;
a shield gate formed in a lower portion of each one of the plurality of trenches, wherein the shield gate comprises a first shield gate and a second shield gate which is wider than the first shield gate in a lateral direction;
a first dielectric layer insulating the second shield gate from the trench in each one of the plurality of trenches;
a second dielectric layer, together with the first dielectric layer, insulating the first shield gate from the trench in each one of the plurality of trenches;
a control gate formed in an upper portion of the trench in each one of the plurality of trenches, wherein the control gate is insulated from the shield gate by an intermediate insulating layer; and
a gate dielectric layer insulating the control gate from the trench and covering the control gate in each one of the plurality of trenches.

9. The trench gate MOSFET of claim 8, further comprising:
body regions formed in the epitaxial layer, wherein each one of the plurality of trenches is flanked by two body regions;
source regions formed in the body regions respectively.

10. The trench gate MOSFET of claim 8, wherein the first dielectric layer comprises a first insulating layer and a second insulating layer conformal with the first insulating layer, and wherein the first insulating layer adjoins an inner surface of the trench, and the second insulating layer adjoins the second dielectric layer.

11. The trench gate MOSFET of claim 10, wherein the first insulating layer comprises an oxide layer and the second insulating layer comprises a nitride layer.

12. The trench gate MOSFET of claim 10, wherein the first insulating layer has a thickness ranging from 0.1 µm to 0.3 µm, and the second insulating layer has a thickness ranging from 0.2 µm to 0.4 µm.

13. The trench gate MOSFET of claim 8, wherein the second dielectric layer comprises an oxide layer.

14. The trench gate MOSFET of claim 8, wherein in a direction vertical to the first surface of the epitaxial layer, the epitaxial layer sequentially comprises a lightly doped layer, a moderately doped layer and a heavily doped layer, with the heavily doped layer being closest to the semiconductor substrate.
